(19) United States
(12) Patent Application Publication
(10) Pub. No.: US 2026/0178804 A1
(43) Pub. Date: Jun. 25, 2026

(54) TRANSMISSION SYSTEM BEARING INTERFACE MODELING METHOD, SYSTEM, AND STORAGE MEDIUM

(71) Applicant: Jilin University, Changchun (CN)

(72) Inventors: Konghua Yang, Changchun (CN); Chunbao Liu, Changchun (CN); Haoyu Wang, Changchun (CN); Yuxiao Tang, Changchun (CN); Luquan Ren, Changchun (CN)

(21) Appl. No.: 19/432,021

(22) Filed: Dec. 23, 2025

(30) Foreign Application Priority Data
Dec. 24, 2024 (CN) 202411908816.4

(51) Int. Cl. G06F 30/28

(52) U.S. Cl. CPC G06F 30/28

(57) ABSTRACT

A transmission system bearing interface modeling method includes the steps of: establishing a three-dimensional (3D) model of a bearing interface, and performing grid generation for a fluid domain of the bearing interface within the 3D model; determining simulation operating conditions, modeling the fluid domain using a volume of fluid (VOF) model, and capturing phase interfaces in multiphase flow within a gear transmission; modeling a solid domain of the bearing interface using a thermal network model, and discretizing the solid domain into a plurality of temperature nodes; calculating frictional heat generation of a gear pair to obtain heat sources under meshing conditions, and applying the heat sources to the thermal network model for simulation; and packaging the modeled bearing interface into an analysis system to calculate a heat source of the bearing interface. Reference can be provided for temperature variation and multiphase flow behavior in gear transmissions, improving research efficiency.

### CROSS-REFERENCE TO RELATED APPLICATION

This application claims priority of Chinese Patent Application No. 202411908816.4, filed on Dec. 24, 2024, the entire contents of which are incorporated herein by reference.

### TECHNICAL FIELD

The present disclosure relates to the technical filed of gear transmission, and particularly to a transmission system bearing interface modeling method, system, and storage medium.

### BACKGROUND

The demand for high-speed, high-power-density helical gear transmissions is continuously increasing in special vehicles, aerospace, and offshore vessels. Gear reducers with splash lubrication characteristics are one of key transmission components meeting this trend. Effective lubrication and thermal reliability are crucial for the efficiency and stability of gear reducers, making it necessary to investigate the complex thermal-flow coupling process inside the gear reducers.

For transmission systems, a time scale of thermal diffusion is typically 102 to 105 times longer than that of multiphase flow. Current numerical methods predominantly employ equal time steps to solve for information of each physical field in a fluid domain and a solid domain. While adaptive thermal evolution of a gear body can be achieved in principle, the prohibitive computational cost renders the investigation of temperature variation and multiphase flow behavior within gear reducers impractical in practice.

Therefore, it is necessary to provide a cross-time-scale multiphysics coupling modeling method for transmission systems to solve the aforementioned problems.

### SUMMARY

To solve the aforementioned problems, the present disclosure provides a transmission system bearing interface modeling method, system, and storage medium.

In one aspect, the present disclosure provides a transmission system bearing interface modeling method, including the steps of:
establishing a three-dimensional (3D) model of a bearing interface, the bearing interface being a meshing gear pair, and performing grid generation for a fluid domain within the 3D model of the bearing interface;
determining simulation operating conditions, modeling the fluid domain of the bearing interface using a volume of fluid (VOF) model, and capturing phase interfaces in multiphase flow within a gear transmission;
modeling a solid domain of the bearing interface using a thermal network model, and discretizing the solid domain into a plurality of temperature nodes;
calculating frictional heat generation of the gear pair based on gear dynamics to obtain heat sources under meshing conditions, and applying the heat sources to the thermal network model for simulation; and
packaging the modeled bearing interface into an analysis system; and configuring the analysis system with operating condition data of the gear pair as input parameters, and a churning power loss and a temperature variation of the gear pair as output parameters.

Further, the performing grid generation for a fluid domain within the 3D model of the bearing interface includes:
dividing the bearing interface into a driving gear region, a driven gear region, and a gear box body region;
assigning the driving gear region and the driven gear region to a foreground grid and the gear box body region to a background mesh, with foreground grid elements being hybrid hexahedral meshes and background grid elements being structured hexahedral meshes;
establishing an overlapping interface for information transfer between the driving gear region and the gear box body region and between the driven gear region and the gear box body region; and
arranging an inflation layer between wall surfaces of the background grid and the foreground grid to ensure a normalized wall distance.

Further, the simulation operating conditions include an oil immersion depth, a gear rotational speed, and a lubricant oil temperature, and the modeling the fluid domain of the bearing interface using a VOF model includes:
modeling heat transfer and flow in the fluid domain of the model of the bearing interface using the VOF model with the following governing equations for multiphase thermal-flow coupling:
a continuity equation:

$$\frac{\partial ρ}{\partial t} + ∇ ( ρ \vec{u} ) = 0 ,$$

where ρ is a fluid density, t is time, and \vec{u} is a fluid velocity vector;
momentum equations:

$$\frac{\partial }{\partial t} ( ρ \vec{u} ) + ∇ ( p \vec{u} \vec{u} ) = - ∇ P + ∇ ( μ ( ∇ \vec{u} + ∇ {\vec{u}}^{T} ) ) + ρ \vec{g} + \vec{F} , and \vec{F} = σ \frac{{ψ}_{a} {ρ}_{a} {κ}_{a} ∇ {α}_{a} + {ψ}_{l} {ρ}_{l} {κ}_{l} ∇ {α}_{l}}{\frac{1}{2} ( {ρ}_{a} + {ρ}_{l} )} ,$$

where P is pressure, μ is dynamic viscosity, \vec{g} is gravitational acceleration, \vec{F} is surface tension, σ is a surface tension coefficient, Ψₐ is an air volume fraction, βₐ is an air density, κₐ is an air interface curvature, αₐ is an air volume fraction, Ψₗ is a lubricating oil volume fraction, ρₗ is a lubricating oil density, κₗ is a lubricating oil interface curvature, and αₗ is a lubricating oil volume fraction; and
an energy equation:

$$\frac{\partial }{\partial t} ( ρ E ) + ∇ ( \vec{u} ( ρ E + P ) ) = ∇ ( {k}_{eff} ∇ T ) + {S}_{E} ,$$

where E is energy, k_{eff} is an effective thermal conductivity, T is temperature, and S_{E} is an energy source term;
applying energy from churning losses to the fluid domain as an energy source term SE, according to the following formula:

$${S}_{E} = \frac{{ψ}_{l} \vert ( {M}_{P} + {M}_{P , a x l e} ) {n}_{P} - ( {M}_{G} + {M}_{G , a x l e} ) {n}_{G} \vert}{9550 {V}_{l}} ,$$

where M_{P} and M_{P,axle} represent a churning torque of the driving gear and a churning torque of the driving gear axle; M_{G} and M_{G,axle} represent a churning torque of the driven gear and a churning torque of the driven gear axle, respectively; n_{P} and n_{G} represent a rotational speed of the driving gear and a rotational speed of the driven gear; and Vₗ is a total lubricating oil volume; and
predicting distribution of each phase using the VOF model, and calculating a mixture density ρ and a mixture viscosity μ for each divided grid cell as follows:

$$ρ = {ψ}_{a} {ρ}_{a} + {ψ}_{l} {ρ}_{l} ,$$

$$μ = {ψ}_{a} {μ}_{a} + {ψ}_{l} {μ}_{l} , and$$

$${ψ}_{a} + {ψ}_{l} = 1 ,$$

where μₐ represents air viscosity, and μₗ represents lubricating oil viscosity; and
when Ψₐ=1, it indicates that the grid cell is filled with air; and when Ψₗ=0, it indicates that the grid cell contains no lubricating oil.

Further, the modeling a solid domain of the bearing interface using a thermal network model, and discretizing the solid domain into a plurality of temperature nodes include:
discretizing a driving gear, a driving gear axle, a driven gear, and a driven gear axle into 6, 14, 12, and 13 temperature nodes, respectively;
requiring the following energy equation to be satisfied at each temperature nod TN:

$${\sum }_{j = 1}^{n} {Q}_{i j} + {S}_{i} = {ρ}_{i} {V}_{i} C {p}_{i} \frac{d {T}_{TN , i}}{d t} ,$$

where Qᵢⱼ is a heat transfer rate between a temperature node TNⱼ and a temperature node TNᵢ; Sᵢ is a heat source added to TNᵢ; ρᵢ, Vᵢ, Cpᵢ, and T_{TN,i} are a density, volume, specific heat capacity, and temperature of TNᵢ, respectively; and n is number of temperature nodes; and
establishing transient iterative energy expressions for each temperature node TN of the gear pair based on the energy equation, as follows:
heat transfer at tooth tip nodes:

$$\frac{2 ( {T}_{ave , fluid} - {T}_{TN , 1} )}{{R}_{c}} + \frac{{T}_{TN , 2} - {T}_{TN , 1}}{{R}_{d , gear}} + S = {ρ}_{i} {V}_{i} C {p}_{i} \frac{{T}_{TN , 1}^{t + 1} - {T}_{TN , 1}}{Δ t} ,$$

where T_{ave,fluid} is an average fluid temperature; T_{TN,1} is a temperature node at a tooth tip; T_{TN,2} is a temperature node on a gear body close to an outer side thereof and adjacent to the tooth tip; S is a heat source added to temperature node

$${T}_{TN , 1} ; {T}_{TN , 1}^{t + 1}$$

is a temperature of the temperature node at the tooth tip (T_{TN,1}) at time step t+1; Δt is an iteration time step for the solid domain; R_{c} is a convective heat transfer resistance; and R_{d,gear} is a thermal resistance between nodes on the gear body;
heat transfer of gear body nodes along a radial direction:

$$\frac{2 ( {T}_{ave , fluid} - {T}_{TN , 2} )}{{R}_{c}} + \frac{{T}_{TN , 1} - {T}_{TN , 2}}{{R}_{d , gear}} + \frac{{T}_{TN , 3} - {T}_{TN , 2}}{{R}_{d , gear}} = {ρ}_{i} {V}_{i} {Cp}_{i} \frac{{T}_{TN , 2}^{t + 1} - {T}_{TN , 2}}{Δ t} ,$$

where T_{TN,3} is a temperature node adjacent to

$${T}_{TN , 2} ; and {T}_{TN , 2}^{t + 1}$$

is a temperature of the temperature node on the gear body close to the outer side thereof and adjacent to the tooth tip (T_{TN,2}) at time step t+1;
heat transfer between nodes of a gear and a gear axle:

$$\frac{{T}_{TN , m - 1} - {T}_{TN , m}}{{R}_{d , gear}} + \frac{2 ( {T}_{TN , m + 1} - {T}_{TN , m} )}{{R}_{d , axle}} = {ρ}_{i} {V}_{i} C {p}_{i} \frac{{T}_{TN , m}^{t + 1} - {T}_{TN , m}}{Δ t} ,$$

where T_{TN,m-1} is a temperature node in the gear body close to the corresponding axle; T_{TN,m} is a temperature node between the gear body and the axle; T_{TN,m+1} is a temperature node on the axle close to the gear body; R_{d,axle} is a thermal resistance between adjacent nodes on the gear axle; and

$${T}_{TN , m}^{t + 1}$$

is a temperature of the temperature node between the gear body and the axle (T_{TN,m}) at time step t+1;
heat transfer of nodes on the gear axle:

$$\frac{2 ( {T}_{ave , fluid} - {T}_{TN , m + 1} )}{{R}_{c}} + \frac{{T}_{TN , m} - {T}_{TN , m + 1}}{{R}_{d , axle}} + \frac{{T}_{TN , m + 2} - {T}_{TN , m + 1}}{{R}_{d , axle}} = {ρ}_{i} {V}_{i} {Cp}_{i} \frac{{T}_{TN , m + 1}^{t + 1} - {T}_{TN , m + 1}}{Δ t} ,$$

where T_{TN,m+2} is a temperature node on the axle adjacent to temperature node

$${T}_{TN , m + 1} ; and {T}_{TN , m + 1}^{t + 1}$$

is a temperature of the temperature node on the axle close to the gear body (T_{TN,m+1}) at time step t+1; and
heat transfer at nodes on a gear axle end face:

$$\frac{2 ( {T}_{ave , fluid} - {T}_{TN , m + n} )}{{R}_{c}} + \frac{{T}_{TN , m + n - 1} - {T}_{TN , m + n}}{{R}_{d , axle}} = {ρ}_{i} {V}_{i} {Cp}_{i} \frac{{T}_{TN , m + n}^{t + 1} - {T}_{TN , m + n}}{Δ t} ,$$

where T_{TN,m+n} is a temperature node of an axle end face; T_{TN,m+n-1} is a temperature node on the axle adjacent to

$${T}_{TM , m + n} ; and \\ {T}_{TN , m + n}^{t + 1}$$

is a temperature of the temperature node at the axle end face (T_{TN,m+n}) at time step t+1; and
according to heat transfer theory, the thermal resistance between nodes on the gear body R_{d,gear}, is given by:

$${R}_{d , gear} = \frac{ln ( {r}_{out} / {r}_{inner} )}{2 πλ B}$$

where rₒᵤₜ is a radius of an outer TN, which is farther from the axle; rᵢₙₙₑᵣ is a radius of an inner TN, which is closer to the axle; λ is a thermal conductivity; and B is a gear face width;
the thermal resistance between adjacent nodes on the gear axle R_{d,axle} is defined as:

$${R}_{d , axle} = \frac{l}{λ A} ,$$

where l is spacing between temperature nodes, and A is a heat transfer area; and
the convective heat transfer resistance R_{c} is as follows:

$${R}_{c} = \frac{{T}_{TN} - {T}_{a ν e , fluid}}{Q} ,$$

where T_{TN} represents temperature nodes on the gear and the corresponding axle; and Q represents a convective heat transfer rate at wall surfaces of corresponding regions within the fluid domain.

Further, the calculating frictional heat generation of the gear pair based on gear dynamics to obtain heat sources under meshing conditions, and applying the heat sources to the thermal network model for simulation include:
establishing a coordinate system based on gear dynamics and determining each meshing point position during gear pair meshing within the established coordinate system;
calculating a sliding loss and a rolling loss using empirical equations for each meshing point on each line of action;
determining a heat source for the driving gear and a heat source for the driven gear at each meshing point using heat partition coefficients;
calculating an average heat source for each line of action based on the heat source for the driving gear and the heat source for the driven gear at each meshing point;
performing weighted average based on a length of each line of action to obtain a heat source under a current meshing condition;
averaging the heat sources over all computational cycles in a transmission process to obtain an average heat source for the transmission process; and
applying each calculated heat source data to the thermal network model of the solid domain.

Further, the calculating a sliding loss and a rolling loss using empirical equations for each meshing point on each line of action includes:
calculating a comprehensive curvature radius R_{cc} at a meshing point:

$${R}_{CC} = \frac{{R}_{C , P} {R}_{C , G}}{{R}_{C , P} + {R}_{C , G}} ,$$

where R_{C,P} is a curvature radius of the driving gear at the meshing point, and R_{C,G} is a curvature radius of the driven gear at the meshing point;
determining a sliding velocity as follows:

$${V}_{S , P} = {R}_{C , P} \frac{π {n}_{P}}{30} , and \\ {V}_{S , G} = {R}_{C , G} \frac{π {n}_{G}}{30} ,$$

where V_{S,P} is a sliding velocity of the driving gear, V_{S,G} is a sliding velocity of the driven gear, n_{P} is a rotational speed of the driving gear, and n_{G} is a rotational speed of the driven gear;
determining a relative sliding velocity V_{RS} and a rolling velocity V_{RR} as follows:

$${V}_{R S} = \vert {V}_{S , P} - {V}_{S , G} \vert , and \\ {V}_{R R} = \frac{{V}_{S , P} + {V}_{S , G}}{2} ;$$

determining a relative sliding ratio V_{SR} as follows:

$${V}_{S R} = \frac{{V}_{R S}}{{V}_{R R}} ;$$

determining a maximum Hertz contact stress σₘₐₓ as follows:

$${σ}_{max} = \frac{\sqrt{\frac{{F}_{n}}{π {R}_{C C} {L}_{C}} ( \frac{{E}_{P} {E}_{G}}{{E}_{G} ( 1 - {υ}_{P} ) + {E}_{P} ( 1 - {υ}_{G} )} )}}{{10}^{6}} ,$$

where Fₙ is a normal force, L_{C} is a contact line length at a gear meshing point, E_{P} is an elastic modulus of the driving gear, E_{G} is an elastic modulus of the driven gear, ν_{P} is a Poisson's ratio of driving gear material, and ν_{G} is a Poisson's ratio of a driven gear material;
determining a sliding friction coefficient f as follows:

$$f = {e}^{f ( SR , {σ}_{max} , {μ}^{′} , Ra )} {σ}_{max}^{1.03} {\vert SR \vert}^{1.04} {V}_{R R}^{- 0.1} {μ}^{′0 \text{.75}} {R}_{C C}^{- 0.39} , and \\ f ( SR , {σ}_{max} , {μ}^{′} , Ra ) = - 8.92 - 0.35 \vert SR \vert {σ}_{max} {log}_{10} ( {μ}^{′} ) + 2.81 {e}^{- \vert S R \vert {σ}_{max} l o {g}_{10} ( {μ}^{′} )} + 0.62 {e}^{R a} ,$$

where μ′ is a dynamic viscosity of the lubricating oil, Ra is surface roughness of the gear, and SR is a sliding ratio;
determining an effective elastic modulus E_{E} as follows:

$${E}_{E} = \frac{2 \times {10}^{6} {E}_{P} {E}_{G}}{{E}_{G} ( 1 - {υ}_{P} ) + {E}_{P} ( 1 - {υ}_{G} )} ;$$

determining a minimum film thickness hₘ as follows:

$${h}_{m} = \frac{3.07 {γ}^{0.57} {{R}_{C C}^{0.4} ( 1 {0}^{- 3} μ {V}_{R R} )}^{0.71}}{{{E}_{E}^{0.03} ( \frac{{F}_{n}}{{L}_{C}} )}^{0.11}} ,$$

where γ is a pressure-viscosity coefficient of the lubricating oil, and μ is a dynamic viscosity of the lubricating oil; and
determining a sliding loss P_{S} and a rolling loss P_{R} as follows:

$${P}_{S} = f {F}_{n} {V}_{S} , and \\ {P}_{R} = \frac{9 \times 1 {0}^{7} {V}_{R R} {h}_{m} {B}^{′} {ε}_{α}}{cos {β}_{b}} ,$$

where V_{S} is a relative sliding velocity, B′ is an effective gear face width, εₐ is a transverse contact ratio, and β_{b} is a helix angle at base circle.

Further, the determining a heat source for the driving gear and a heat source for the driven gear at each meshing point using heat partition coefficients includes:
calculating a heat partition coefficient for the driving gear and a heat partition coefficient for the driven gear using the following formulas:

$${η}_{P} = \frac{\sqrt{{λ}_{P} {ρ}_{P} {Cp}_{P} {V}_{S , P}}}{\sqrt{{λ}_{P} {ρ}_{P} {Cp}_{P} {V}_{S , P}} + \sqrt{{λ}_{G} {ρ}_{G} {Cp}_{G} {V}_{S , G}}} , and \\ {η}_{G} = 1 - {η}_{P} ,$$

where η_{P} is a heat partition coefficient of the driving gear, η_{G} is a heat partition coefficient of the driven gear, λ_{P} is a thermal conductivity of the driving gear, ρ_{P} is a density of the driving gear, Cρ_{P} is a specific heat capacity of the driving gear, λ_{G} is a thermal conductivity of the driven gear, ρ_{G} is a density of the driven gear, and Cρ_{G} is a specific heat capacity of the driven gear; and

calculating a heat source S_{P} generated by heat during driving gear meshing and a heat source S_{G} generated by heat during driven gear meshing based on the heat partition coefficients using the following formulas:

$${S}_{P} = {η}_{P} ( {P}_{S} + {P}_{R} ) , and \\ {S}_{G} = {η}_{G} ( {P}_{S} + {P}_{R} ) .$$

Further, the packaging the modeled bearing interface into an analysis system includes:
integrating a fluid domain modeling calculation method, a solid-domain thermal network method, and a gear frictional heat calculation method into a unified system; configuring the system with an oil immersion depth, a rotational speed, and a lubricant oil temperature as input parameters, and a churning power loss and a temperature variation of the gear pair as output parameters; and operating the system to acquire operating condition data of the gear pair at the bearing interface, perform simulation calculations on the acquired operating condition data via the integrated computational methods, and output heat source calculation results for the bearing interface, achieving a comparative analysis between the simulation results and experimental data.

In another aspect, the present disclosure provides a transmission system bearing interface modeling system, including a memory storing a computer program, and a processor, which, when executing the computer program, implements the steps of the transmission system bearing interface modeling method as described above.

In yet another aspect, the present disclosure provides a storage medium, having stored thereon a computer program, which, when executed by the processor, causes the processor to perform the steps of the transmission system bearing interface modeling method as described above.

An embodiment of the present disclosure provides a transmission system bearing interface modeling method, which includes the steps of: employing an overset grid and a VOF model to compute evolution of multiphase flow within a gear transmission; discretizing a gear body into a plurality of temperature nodes and thermal resistances to establish a thermal network model of a solid domain for temperature field iteration of the gear body; determining a position of any meshing point based on a coordinate system derived from gear dynamics; calculating a heat source for a driving gear and a heat source for a driven gear at each meshing point by combining empirical formulas, fluid dynamics data, and heat partition coefficients; applying the calculated heat sources to the thermal network model of the solid domain for computation; integrating a fluid domain modeling calculation method, a solid-domain thermal network method, and a gear frictional heat calculation method into a unified system; and configuring the unified system with an oil immersion depth, a rotational speed, and a lubricant oil temperature as input parameters, and a churning power loss and a temperature variation of a gear pair as output parameters, thereby achieving rapid comparative analysis between simulation results and experimental data under identical operating conditions.

The present disclosure can achieve rapid thermal response of the gear body to multiphase thermal-flow field data by performing iterative simulations in the fluid and solid domains with respective smaller and larger time steps. As a result, realistic multiphase thermal-flow behavior and adaptive temperature evolution of the gear body are captured at a reduced computational cost, thereby providing a reference for studying temperature variation and multiphase flow behavior inside helical gear reducers, while significantly enhancing research efficiency.

### BRIEF DESCRIPTION OF THE DRAWINGS

The accompanying drawings herein are provided to facilitate a better understanding of the present disclosure and constitute a part of the present application. The illustrative embodiments of the present disclosure and the descriptions thereof are intended to explain the present disclosure and are not be construed as unduly limiting the present disclosure. In the accompanying drawings:

FIG. 1 is a flow diagram of a transmission system bearing interface modeling method according to an embodiment of the present disclosure.

FIG. 2 is a schematic structural diagram of a gear pair.

FIG. 3 is a schematic diagram of an overset grid in a model of a bearing interface.

FIG. 4 is a schematic diagram showing a data exchange strategy in the model of the bearing interface.

FIG. 5 is a schematic diagram showing various surface types of the gear pair in a thermal network model.

FIG. 6A is a schematic diagram of a heat transfer mechanism; and

FIG. 6B is a schematic diagram of a thermal network model of a solid domain.

FIG. 7 is a schematic diagram showing a method for determining meshing point positions during gear meshing.

FIG. 8 is a schematic diagram of a transmission system bearing interface modeling system.

### DETAILED DESCRIPTION

To facilitate a better understanding of the solutions of the present application by those of skill in the art, the technical solutions in the embodiments of the present application are further described clearly and completely below in combination with the accompanying drawings. Obviously, the embodiments are only part of the embodiments of the present application, rather than all embodiments. Based on the embodiments of the present application, all other embodiments obtained by those of ordinary skill in the art without creative efforts fall within the scope of protection of the present application. It is to be noted that the embodiments of the present application and features therein may be mutually combined without technical conflict.

Furthermore, the terms “an embodiment” or “embodiment” as used herein refer to specific features, structures, or characteristics that may be incorporated in at least one implementation of the present disclosure. The phrase “in one embodiment” appearing at various places in this specification does not necessarily all refer to the same embodiment, nor are they separate or alternative embodiments that are mutually exclusive from other embodiments.

Furthermore, the terms “include,” “have”, and any variants thereof are intended to cover a non-exclusive inclusion. For example, a process, method, product, or device that includes a series of steps or units is not necessarily limited to those expressly listed steps or units, but may include other steps or units not expressly listed or inherent to such process, method, product, or device.

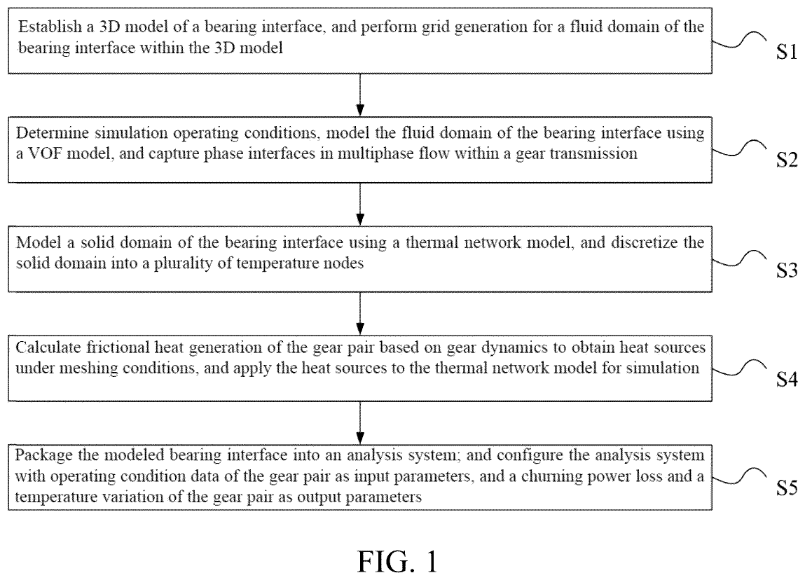

Embodiment 1: referring to FIG. 1, FIG. 1 is a flow diagram of a transmission system bearing interface modeling method according to an embodiment of the present disclosure. As shown in FIG. 1, the method includes the following steps:

In S1, a 3D model of a bearing interface is established, and grid generation is performed for a fluid domain within the 3D model of the bearing interface.

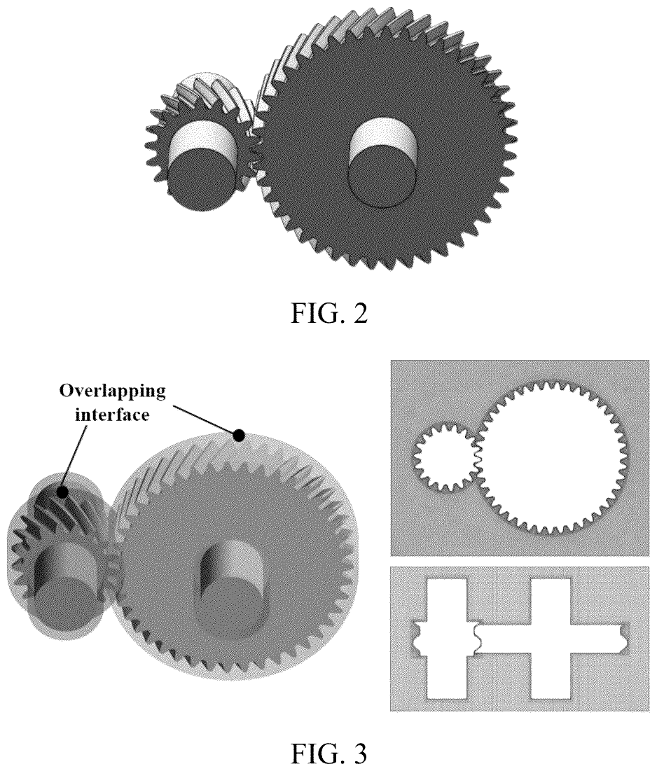

The bearing interface refers to the part of a transmission system that bears loads and stresses, and its performance directly affects the overall performance and service life of the transmission system. In vehicle transmission systems, the bearing interface is typically a meshing gear pair. A gear pair is a transmission device including two or more gears. It transmits rotational power and alters speed and torque through meshing points. Referring to FIG. 2, FIG. 2 is a schematic structural diagram of the gear pair. As shown in FIG. 2, the gear pair in this embodiment is a pair of meshing helical gears, including a driving gear and a driven gear.

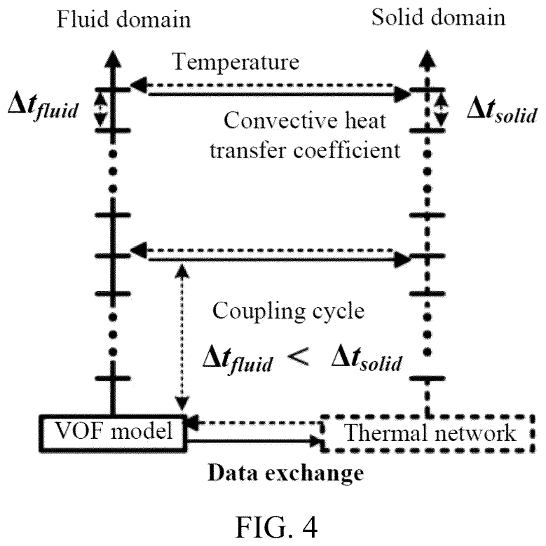

In S1, the 3D model of the bearing interface may be implemented using modeling software such as AutoCAD, 3ds Max, SolidWorks, etc. After the 3D model of the gear pair is established, grid generation needs to be performed for a fluid domain within the 3D model (i.e., a region through which fluids such as lubricating oil flow). Grid generation forms the foundation of numerical simulation, as it discretizes the continuous fluid domain into a series of small elements to facilitate numerical computation. In this embodiment, a fluid domain grid is generated through the following procedure: the bearing interface is divided into a driving gear region, a driven gear region, and a gear box body region; the driving gear region and the driven gear region are assigned to a foreground mesh, while the gear box body region serves as a background mesh; background grid elements are structured hexahedral meshes, and foreground grid elements are hybrid polyhedral-hexahedral meshes; an appropriate inflation layer is arranged near wall surfaces of the background grid and the foreground grid to ensure a normalized wall distance; and overlapping interfaces are established between the driving gear region and the gear box body region as well as between the driven gear region and the gear box body region. Referring to FIG. 3, FIG. 3 is a schematic diagram of an overset grid in the model of the bearing interface. Information transfer between the driving gear region and the gear box body region as well as between the driven gear region and the gear box body region is achieved through the overlapping interfaces.

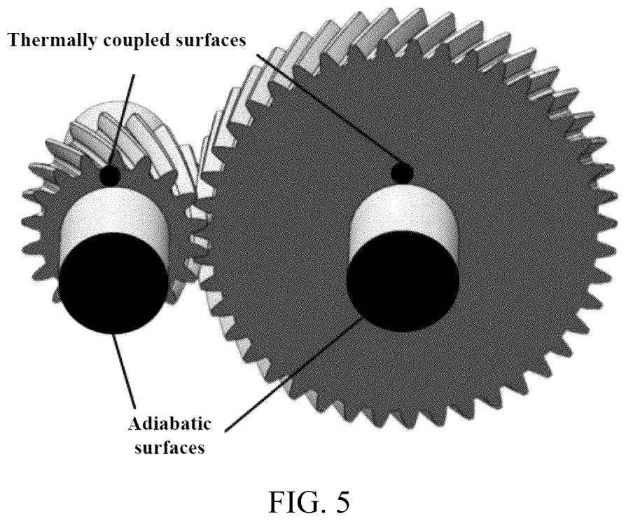

Referring to FIG. 4, FIG. 4 is a schematic diagram showing a data exchange strategy in the model of the bearing interface. As shown in FIG. 4, in this embodiment, the modeling of the transmission system bearing interface primarily includes a fluid domain and a solid domain, which are addressed using a VOF model and a thermal network model, respectively. The VOF model is a numerical method used for simulating multiphase flow, capable of accurately tracking changes in phase interfaces (e.g., oil-air interfaces). By employing the VOF model, variations in phase interfaces within the multiphase flow of a gear transmission can be simulated, thereby facilitating analysis of fluid's effects on the gear pair. The solid domain of the gear pair (including components such as gear bodies and bearings) is modeled using a thermal network model. This thermal network model discretizes the solid domain into a plurality of temperature nodes and describes the overall temperature distribution through heat conduction relationships between the nodes.

In any coupled cycle, although the number of iterations is the same for both the fluid domain and the solid domain, a time step for the fluid domain (Δt_{fluid}) is smaller than that for the solid domain (Δt_{solid}). When the coupling criterion is met, a convective heat transfer coefficient (h) at wall surfaces of the gears and axles in the fluid domain is transferred to the thermal network model for calculating a convective thermal resistance, while a temperature of each node in the thermal network is applied as a constant-temperature boundary condition at the corresponding position in the fluid domain.

Furthermore, any transient simulation may experience significant fluctuations in simulation data due to numerical iterative instability. To prevent decoupling of the coupled simulation caused by large data deviations, a loosely coupled simulation framework is selected in this embodiment to appropriately scale the coupled data. The convective heat transfer coefficient h during a data-coupling phase is defined as:

$$h = {\sum }_{i = 1}^{N} τ {h}_{i} and τ = \frac{1}{N} ,$$

where τ and N are a relaxation factor and number of iterations per coupling cycle, respectively; and hᵢ is a convective heat transfer coefficient at each iteration.

In S2, simulation operating conditions are determined, the fluid domain of the bearing interface is modeled using the VOF model, and phase interfaces are captured in multiphase flow within a gear transmission.

The simulation operating conditions includes an oil immersion depth, a gear rotational speed, and a lubricant oil temperature. Heat transfer and flow in the fluid domain of the model of the bearing interface constitute a multiphase thermal-flow coupling problem. In this embodiment, the VOF model is employed, governing equations of which are as follows:
a continuity equation:

$$\frac{\partial ρ}{\partial t} + ∇ ( ρ \vec{u} ) = 0 ,$$

where ρ is a fluid density, t is time, and \vec{u} is a fluid velocity vector;
momentum equations:

$$\frac{\partial }{\partial t} = ( ρ \vec{u} ) + ∇ ( ρ \vec{u} \vec{u} ) = - ∇ P + ∇ ( μ ( ∇ \vec{u} + ∇ {\vec{u}}^{T} ) ) + ρ \vec{g} + \vec{F} , and \\ \vec{F} = σ \frac{{ψ}_{a} {ρ}_{a} {κ}_{a} ∇ {α}_{a} + {ψ}_{l} {ρ}_{l} {κ}_{l} ∇ {α}_{l}}{\frac{1}{2} ( {ρ}_{a} + {ρ}_{l} )} ,$$

where P is pressure, μ is dynamic viscosity, \vec{g} is gravitational acceleration, \vec{F} is surface tension, σ is a surface tension coefficient, Ψₐ is an air volume fraction, ρₐ is an air density, κₐ is an air interface curvature, αₐ is an air volume fraction, Ψₗ is a lubricating oil volume fraction, ρₗ is a lubricating oil density, κₗ is a lubricating oil interface curvature, and αₗ is a lubricating oil volume fraction; and
an energy equation:

$$\frac{\partial }{\partial t} ( ρ E ) + ∇ ( \vec{u} ( ρ E + P ) ) = ∇ ( {k}_{eff} ∇ T ) + {S}_{E} ,$$

where E is energy, k_{eff} is an effective thermal conductivity, T is temperature, and S_{E} is an energy source term.

As currently implemented, software such as ANSYS Fluent does not support the calculation of wall frictional heating. Therefore, energy from churning losses is applied to the fluid domain as an energy source term S_{E}, according to the following formula:

$${S}_{E} = \frac{{ψ}_{l} \vert ( {M}_{P} + {M}_{P , axle} ) {n}_{P} - ( {M}_{G} + {M}_{G , axle} ) {n}_{G} \vert}{9550 {V}_{l}} ,$$

where M_{P} and M_{P,axle} represent a churning torque of the driving gear and a churning torque of the driving gear axle (units: N·m); M_{G} and M_{G,axle} represent a churning torque of the driven gear and a churning torque of the driven gear axle, respectively; n_{P} and n_{G} represent a rotational speed of the driving gear and a rotational speed of the driven gear (units: RPM); and Vₗ is a total lubricating oil volume (units: m³).

Distribution of each phase is predicted using the VOF model, and a mixture density ρ and a mixture viscosity μ are calculated for each divided grid cell as follows:

$$ρ = {ψ}_{a} {ρ}_{a} + {ψ}_{l} {ρ}_{l} , \\ μ = {ψ}_{a} {μ}_{a} + {ψ}_{l} {μ}_{l} , and$$

$${ψ}_{a} + {ψ}_{l} = 1 ,$$

where μₐ represents air viscosity, and μₗ represents lubricating oil viscosity; and
when Ψₐ=1, it indicates that the grid cell is filled with air; and when Ψₗ=0, it indicates that the grid cell contains no lubricating oil.

In S3, a solid domain of the bearing interface is modeled using a thermal network model, and discretized into a plurality of temperature nodes.

To achieve rapid temperature field iteration, this embodiment employs a thermal network model for the solid domain. The thermal network model is a mathematical approach used for simulating and analyzing heat conduction, convection, and radiation processes. It operates by discretizing the system into a series of temperature nodes (TNs) and connecting these nodes via thermal resistances (including conductive and convective thermal resistances), thereby simulating heat flow within the system.

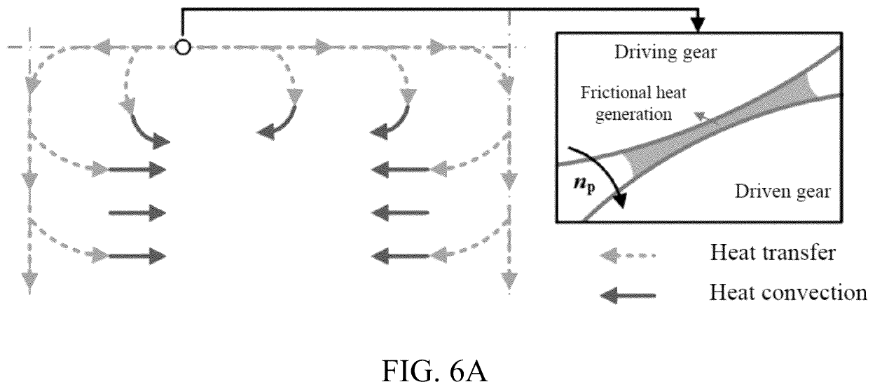

Referring to FIG. 5, which is a schematic diagram showing various surface types of the gear pair in the thermal network model, surfaces of the gear pair body are primarily categorized into two types: thermally coupled surfaces and adiabatic surfaces. As shown, end faces of the gear axles are adiabatic surfaces, while the remaining surfaces of the gears and axles are thermally coupled surfaces.

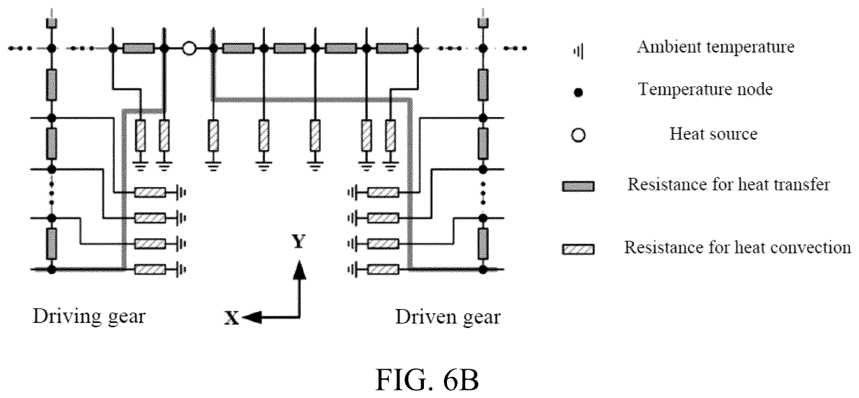

Referring to FIGS. 6A and 6B, FIG. 6A shows heat transfer paths in the driving and driven gears of a gear transmission. Frictional heat is generated by the relative sliding and rolling during gear meshing. Given that the thermal conductivity of the metal gear is significantly higher than that of the lubricating oil, most of the heat initially enters the gear and diffuses internally from the tooth tip towards the shaft end. This conductive process can be modeled by the thermal conductive resistance R_{d}. Ultimately, the heat is transferred to the lubricating oil and the surrounding air via thermal convection, a process that can be simulated by the convective thermal resistance R_{c}.

Based on the heat transfer and generation processes depicted in FIG. 6A, a thermal network model for the gears within the gear transmission system can be established, as shown in FIG. 6B. The heat source (S), temperature node (TN), conductive thermal resistance (R_{d}), and convective thermal resistance (R_{c}) are represented by open circles, solid dots, solid rectangular blocks, and hatched rectangular blocks, respectively. In this model, the heat source indicates a position of heat generation, such as gear meshing surfaces. The solid domain (e.g., gears and gear axles) is discretized into a plurality of temperature nodes, which represent the thermal states at discrete positions within the solid domain. Conductive thermal resistances are connected to adjacent temperature nodes, simulating the heat conduction process inside the solid domain. Convective thermal resistances are connected to the temperature nodes with the ambient environment (e.g., lubricating oil and air), modeling the heat transfer to the surroundings via convection.

The calculation of R_{c} requires temperature node TN regions to match the grid resolution of the fluid domain. Therefore, temperature node TN discretization regions on the gears and axles do not need to be overly refined. In this embodiment, the driving gear, the driving gear axle, the driven gear, and the driven gear axle are discretized into 6, 14, 12, and 13 temperature nodes, respectively. All temperature node TN regions are grouped into M sections on the gears and N sections on the gear axles. Numerical and alphabetical subscripts of TN indicate its specific location. By determining temperatures of these nodes, the temperature distribution across the entire solid domain can be determined.

The following energy equation requires to be satisfied at each temperature nod TN:

$${\sum }_{j = 1}^{n} {Q}_{ij} + {S}_{i} = {ρ}_{i} {V}_{i} {Cp}_{i} \frac{{dT}_{TN , i}}{dt} ;$$

where Qᵢⱼ is a heat transfer rate between a temperature node TNⱼ and a temperature node TNᵢ; Sᵢ is a heat source added to TNᵢ; ρᵢ, Vi, Cpᵢ, and T_{TN,i} are a density, volume, specific heat capacity, and temperature of TNᵢ, respectively; and n is number of temperature nodes.

Based on the energy equation, transient iterative energy expressions are established for each temperature node TN of the gear pair, as follows:
heat transfer at tooth tip nodes:

$$\frac{2 ( {T}_{ave , fluid} - {T}_{TN , 1} )}{{R}_{c}} + \frac{{T}_{TN , 2} - {T}_{TN , 1}}{{R}_{d , gear}} + S = {ρ}_{i} {V}_{i} {Cp}_{i} \frac{{T}_{TN , 1}^{t + 1} - {T}_{TN , 1}}{Δ t} ,$$

where T_{ave,fluid} is an average fluid temperature; T_{TN,1} is a temperature node at a tooth tip; T_{TN,2} is a temperature node on a gear body close to an outer side thereof and adjacent to the tooth tip; S is a heat source added to temperature node

$${T}_{TN , 1} ; {T}_{TN , 1}^{t + 1}$$

is a temperature of the temperature node at the tooth tip (T_{TN,1}) at time step t+1; Δt is an iteration time step for the solid domain; R_{c} is a convective heat transfer resistance; and R_{d,gear} is a thermal resistance between nodes on the gear body;
heat transfer of gear body nodes along a radial direction:

$$\frac{2 ( {T}_{ave , fluid} - {T}_{TN , 2} )}{{R}_{c}} + \frac{{T}_{TN , 1} - {T}_{TN , 2}}{{R}_{d , gear}} + \frac{{T}_{TN , 3} - {T}_{TN , 2}}{{R}_{d , gear}} = {ρ}_{i} {V}_{i} {Cp}_{i} \frac{{T}_{TN , 2}^{t + 1} - {T}_{TN , 2}}{Δ t} ,$$

where T_{TN,3} is a temperature node adjacent to

$${T}_{TN , 2} ; and {T}_{TN , 2}^{t + 1}$$

is a temperature of the temperature node on the gear body close to the outer side thereof and adjacent to the tooth tip (T_{TN,2}) at time step t+1;
heat transfer between nodes of a gear and a gear axle:

$$\frac{{T}_{TN , m - 1} - {T}_{TN , m}}{{R}_{d , gear}} + \frac{2 ( {T}_{TN , m + 1} - {T}_{TN , m} )}{{R}_{d , axle}} = {ρ}_{i} {V}_{i} {Cp}_{i} \frac{{T}_{TN , m}^{t + 1} - {T}_{TN , m}}{Δ t} ,$$

where T_{TN,m-1} is a temperature node in the gear body close to the corresponding axle; T_{TN,m} is a temperature node between the gear body and the axle; T_{TN,m+1} is a temperature node on the axle close to the gear body; R_{d,axle} is a thermal resistance between adjacent nodes on the gear axle; and

$${T}_{TN , m}^{t + 1}$$

is a temperature of the temperature node between the gear body and the axle (T_{TN,m}) at time step t+1;
heat transfer of nodes on the gear axle:

$$\frac{2 ( {T}_{ave , fluid} - {T}_{TN , m + 1} )}{{R}_{c}} + \frac{{T}_{TN , m} - {T}_{TN , m + 1}}{{R}_{d , axle}} + \frac{{T}_{TN , m + 2} - {T}_{TN , m + 1}}{{R}_{d , axle}} = {ρ}_{i} {V}_{i} {Cp}_{i} \frac{{T}_{TN , m + 1}^{t + 1} - {T}_{TN , m + 1}}{Δ t} ,$$

where T_{TN,m+2} is a temperature node on the axle adjacent to temperature node

$${T}_{TN , m + 1} ; and {T}_{TN , m + 1}^{t + 1}$$

is a temperature of the temperature node on the axle close to the gear body (T_{TN,m+1}) at time step t+1; and
heat transfer at nodes on a gear axle end face:

$$\frac{2 ( {T}_{aνe , fluid} - {T}_{TN , m + n} )}{{R}_{c}} + \frac{{T}_{TN , m + n - 1} - {T}_{TN , m + n}}{{R}_{d , axle}} = {ρ}_{i} {V}_{i} {Cp}_{i} \frac{{T}_{TN , m + n}^{t + 1} - {T}_{TN , m + n}}{Δ t} ,$$

where T_{TN,m+n} is a temperature node of an axle end face; T_{TN,m+n-1} is a temperature node on the axle adjacent to

$${T}_{TN , m + n} ; and {T}_{TN , m + n}^{t + 1}$$

is a temperature of the temperature node at the axle end face (T_{TN,m+n}) at time step t+1.

According to heat transfer theory, the thermal resistance between nodes on the gear body R_{d,gear}, is given by:

$${R}_{d , gear} = \frac{ln ( {r}_{out} / {r}_{inner} )}{2 πλ B} ,$$

where rₒᵤₜ is a radius of an outer TN, which is farther from the axle; rᵢₙₙₑᵣ is a radius of an inner TN, which is closer to the axle; λ is a thermal conductivity; and B is a gear face width.

The thermal resistance between adjacent nodes on the gear axle R_{d,axle} is defined as:

$${R}_{d , axle} = \frac{l}{λ A} ,$$

where l is spacing between temperature nodes, and A is a heat transfer area.

The convective heat transfer resistance R_{c} is as follows:

$${R}_{c} = \frac{{τ}_{TN} - {T}_{ave , fluid}}{Q} ,$$

where T_{TN} represents temperature nodes on the gear and the corresponding axle; and Q represents a convective heat transfer rate at wall surfaces of corresponding regions within the fluid domain.

In S4, frictional heat generation of the gear pair is calculated based on gear dynamics to obtain heat sources under meshing conditions, and applying the heat sources to the thermal network model for simulation.

The heat sources in the thermal network model of the solid domain are generated based on the frictional heat generation from gear dynamics. Using the gear dynamics model, meshing point positions of the gear pair are determined at different time steps. A frictional heat generation power during gear meshing is calculated. Based on the meshing conditions and frictional heat generation power, the distribution of heat sources on the gears is determined. Subsequently, the heat source data obtained from the gear dynamics calculations are input into the thermal network model to simulate heat flow.

In this embodiment, a sliding loss and a rolling loss are calculated using empirical equations for each meshing point on each line of action. A heat source for the driving gear and a heat source for the driven gear at each meshing point are determined using heat partition coefficients. An average heat source for each line of action is derived based on the heat sources at each meshing point. A weighted average is performed based on a length of each line of action to obtain a heat source under a current meshing condition. Finally, the heat sources over all computational cycles are averaged to obtain an average heat source for the transmission process. Specifically, S4 includes the following steps:

In S41, a coordinate system is established based on gear dynamics and each meshing point position is determined during gear pair meshing within the established coordinate system.

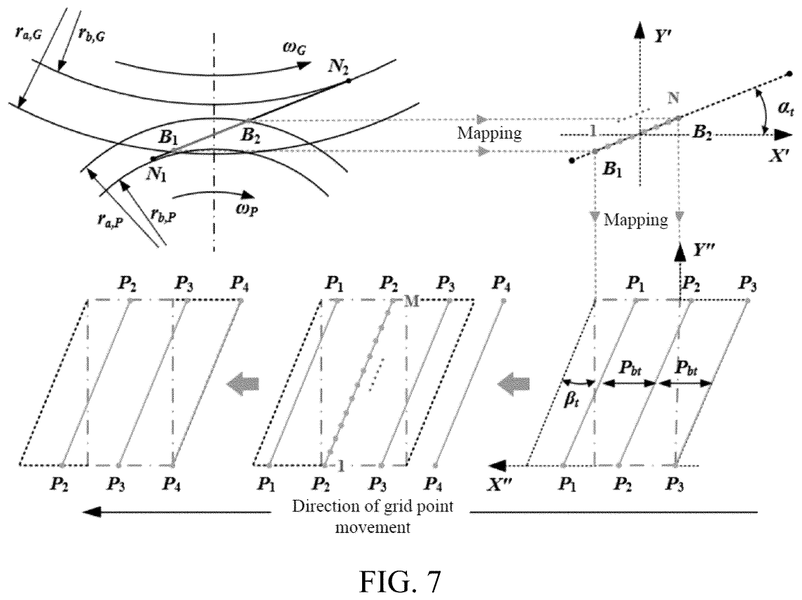

Referring to FIG. 7, FIG. 7 is a schematic diagram showing a method for determining the meshing point positions during gear meshing. As shown in an upper-left part of FIG. 7, the meshing process of the gears is determined based on the design parameters. Using a gear node O and an initial contact point B₁ (where an addendum circle of the driven gear intersects the theoretical line of action N₁N₂) as origins, two coordinate systems are established: the X′Y′ system (upper-right part of FIG. 7) and the X″Y″ system (lower part of FIG. 7), respectively. In the upper-right part of FIG. 7, grid lines are discretized. By establishing a linear function with a slope of tan(aₜ), positions of grid points in the X′Y′ coordinate system are obtained. As shown in the lower part of FIG. 7, in the X″Y″ coordinate system, corresponding lines of action are established based on the meshing points and a base circle helix angle (β_{b}) using linear functions. From these functions, the lengths and number (O) of the lines of action are determined. Subsequently, the positions of the discretized grid points along each line of action in the X′Y′ coordinate system are obtained through coordinate transformation.

In S42, for each meshing point on each line of action, a sliding loss and a rolling loss are calculated using empirical equations.

An empirical equation is a mathematical expression that represents one or more empirical relationships. It is determined based on experience or experimental data.

In this embodiment, a detailed calculation process for sliding and rolling losses using empirical equations is as follows:

A comprehensive curvature radius R_{CC} (unit: m) is calculated at a meshing point:

$${R}_{CC} = \frac{{R}_{C , P} {R}_{C , G}}{{R}_{C , P} + {R}_{C , G}} ,$$

where R_{C,P} is a curvature radius of the driving gear at the meshing point (unit: m), and R_{C,G} is a curvature radius of the driven gear at the meshing point (unit: m).

A sliding velocity is determined as follows:

$$\begin{matrix}{V}_{S , P} = {R}_{C , P} \frac{{π n}_{P}}{30} , and \\ {V}_{S , G} = {R}_{C , G} \frac{{π n}_{G}}{30} ,\end{matrix}$$

where V_{S,P} is a sliding velocity of the driving gear (unit: m/s), V_{S,G} is a sliding velocity of the driven gear (unit: m/s), n_{P} is a rotational speed of the driving gear (unit: RPM), and n_{G} is a rotational speed of the driven gear (unit: RPM).

A relative sliding velocity V_{RS} and a rolling velocity V_{RR} are determined as follows:

$$\begin{matrix}{V}_{RS} = \vert {V}_{S , P} - {V}_{S , G} \vert , and \\ {V}_{RR} = \frac{{V}_{S , P} + {V}_{S , G}}{2} .\end{matrix}$$

A relative sliding ratio V_{SR} is determined as follows:

$${V}_{SR} = \frac{{V}_{RS}}{{V}_{RR}} .$$

A maximum Hertz contact stress σₘₐₓ is determined as follows:

$${σ}_{max} = \frac{\sqrt{\frac{{F}_{n}}{π {R}_{CC} {L}_{C}} ( \frac{{E}_{P} {E}_{G}}{{E}_{G} ( 1 - {υ}_{P} ) + {E}_{P} ( 1 - {υ}_{G} )} )}}{{10}^{6}} ,$$

where Fₙ is a normal force (unit: N), L_{C} is a contact line length at a gear meshing point (unit: mm), E_{P} is an elastic modulus of the driving gear, E_{G} is an elastic modulus of the driven gear, ν_{P} is a Poisson's ratio of driving gear material, and ν_{G} is a Poisson's ratio of a driven gear material.

A sliding friction coefficient f is determined as follows:

$$f = {e}^{f ( SR , {σ}_{max} , μ′ , Ra )} {σ}_{max}^{1.03} {\vert SR \vert}^{1.04} {V}_{RR}^{- 0.1} {μ}^{′0 \text{.75}} {R}_{CC}^{- 0.39} , and$$

$$f ( SR , {σ}_{max} , {μ}^{′} , Ra ) = - 8.92 - 0.35 \vert SR \vert {σ}_{max} {log}_{10} ( {μ}^{′} ) + 2.81 {e}^{- \vert SR \vert {σ}_{max} {log}_{10} ( μ′ )} + 0.62 {e}^{Ra} ,$$

where μ′ is a dynamic viscosity of the lubricating oil (unit: cP), Ra is surface roughness of the gear (unit: μm), and SR is a sliding ratio.

An effective elastic modulus E_{E} (unit: Pa) is determined as follows:

$${E}_{E} = \frac{2 \times {10}^{6} {E}_{P} {E}_{G}}{{E}_{G} ( 1 - {υ}_{P} ) + {E}_{P} ( 1 - {υ}_{G} )} .$$

A minimum film thickness hₘ (unit: m) is determined as follows:

$${h}_{m} = \frac{3.07 {γ}^{0.57} {{R}_{CC}^{0.4} ( 1 {0}^{- 3} μ {V}_{RR} )}^{0.71}}{{{E}_{E}^{0.03} ( \frac{{F}_{n}}{{L}_{C}} )}^{0.11}} ,$$

where γ is a pressure-viscosity coefficient of the lubricating oil (unit: m²/N), and μ is a dynamic viscosity of the lubricating oil.

A sliding loss P_{S} (unit: W) and a rolling loss P_{R} (unit: W) are determined as follows:

$$\begin{matrix}{P}_{S} = {fF}_{n} {V}_{S} , and \\ {P}_{R} = \frac{9 \times 1 {0}^{7} {V}_{RR} {h}_{m} B {′ε}_{α}}{cos {β}_{b}} ,\end{matrix}$$

where Vs is a relative sliding velocity, B′ is an effective gear width (unit: m), εₐ is a transverse contact ratio, and β_{b} is a helix angle at base circle (unit: rad). The base circle is a fundamental concept in gear design, referring to an imaginary circle on an involute (or cycloidal) cylindrical gear. When the generating line (for an involute profile) or the generating circle (for a cycloidal profile) rolls without slipping on the circumference of this imaginary circle, that circle is defined as the base circle.

In S43, a heat source for the driving gear and a heat source for the driven gear at each meshing point are determined using heat partition coefficients.

The heat partition coefficient reflects the proportion of heat distributed between the two contacting surfaces during friction. Using the heat partition coefficients, the heat generated on the driving gear and the driven gear at each meshing point can be calculated.

In this embodiment, a heat partition coefficient for the driving gear and a heat partition coefficient for the driven gear are calculated using the following formulas:

$$\begin{matrix}{η}_{P} = \frac{\sqrt{{λ}_{P} {ρ}_{P} Cp {}_{P} {V}_{S , P}}}{\sqrt{{λ}_{P} {ρ}_{P} Cp {}_{P} {V}_{S , P}} + \sqrt{{λ}_{G} {ρ}_{G} Cp {}_{G} {V}_{S , G}}} , and \\ {η}_{G} = 1 - {η}_{P} ,\end{matrix}$$

where θ_{P}, is a heat partition coefficient of the driving gear, η_{G} is a heat partition coefficient of the driven gear, λ_{P} is a thermal conductivity of the driving gear, ρ_{P} is a density of the driving gear, Cρ_{P} is a specific heat capacity of the driving gear, λ_{G} is a thermal conductivity of the driven gear, ρ_{G} is a density of the driven gear, and Cρ_{G} is a specific heat capacity of the driven gear.

Based on the heat partition coefficients, a heat source S_{P} generated by heat during driving gear meshing and a heat source S_{G} generated by heat during driven gear meshing are calculated using the following formulas:

$$\begin{matrix}{S}_{P} = {η}_{P} ( {P}_{S} + {P}_{R} ) , and \\ {S}_{G} = {η}_{G} ( {P}_{S} + {P}_{R} ) .\end{matrix}$$

In S44, an average heat source is calculated for each line of action based on the heat source for the driving gear and the heat source for the driven gear at each meshing point.

The average heat source for each line of action is calculated by summing the heat sources from all meshing points along that line and dividing by the number of meshing points.

In S45, a weighted average is performed based on a length of each line of action to obtain a heat source under a current meshing condition.

The heat source under the current meshing state represents the total heat generated by friction throughout the ongoing meshing process. The overall heat source under the current meshing state is obtained through the weighted average, where a weighting factor for each line of action is determined based on its length.

In S46, the heat sources over all computational cycles are averaged in a transmission process to obtain an average heat source for the transmission process.

The average heat source facilitates the assessment of thermal effects in the gear pair during long-term operation. It is obtained by averaging the heat sources over all meshing cycles throughout the transmission process.

In this embodiment, a calculation process of frictional heat is divided into three main parts. The coordinate system based on gear dynamics is established to determine the positions of all grid points. Subsequently, by integrating empirical formulas, CFD data, and the heat partition coefficients, the individual heat sources for the driving gear and the driven gear at each meshing point are computed. Finally, the average heat source for the entire transmission process is obtained through a two-step averaging procedure.

In S47, each calculated heat source data is applied to the thermal network model of the solid domain.

The calculated heat source data, including the heat sources for both the driving gear and the driven gear at each meshing point, the average heat source per line of action, the heat source under the current meshing state, and the average heat source over the transmission process, are applied to the thermal network model of the solid domain, allowing thermal effects of the gear pair during operation to be accurately represented.

In S5, the modeled bearing interface is packaged into an analysis system; and the analysis system is configured with operating condition data of the gear pair as input parameters, and a churning power loss and a temperature variation of the gear pair as output parameters.

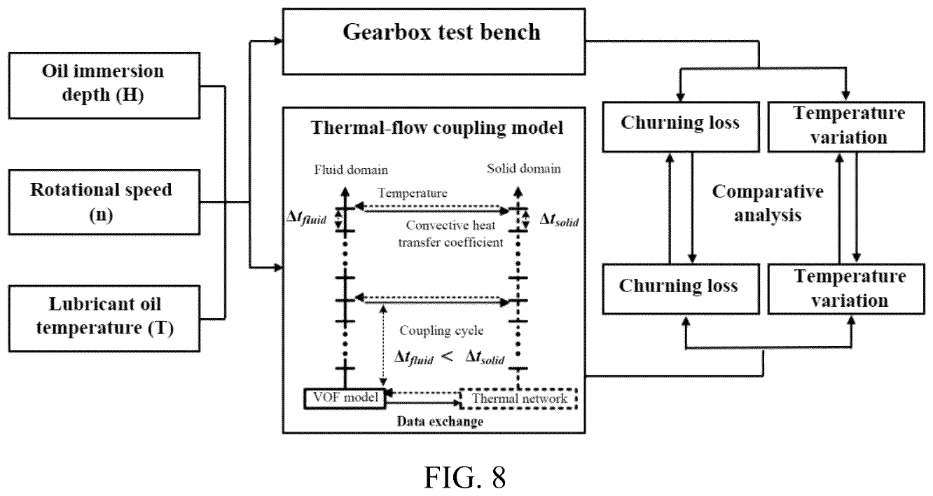

Referring to FIG. 8, FIG. 8 is a schematic diagram of a transmission system bearing interface modeling system. In an embodiment of the present disclosure, a fluid domain modeling calculation method, a solid-domain thermal network method, and a gear frictional heat calculation method are integrated into a unified system. The thermal network model is coupled with the VOF model to exchange data, thereby determining physical field information in both the fluid domain and the solid domain. The system is configured with an oil immersion depth H, a rotational speed n, and a lubricant oil temperature T as input parameters, and a churning power loss and a temperature variation of the gear pair as output parameters. By acquiring operating condition data of the gear pair at the bearing interface, the system performs simulation calculations on the acquired operating condition data via the integrated computational methods, and outputs heat source prediction results for the bearing interface, thereby achieving a comparative analysis between the simulation results and experimental data.

An embodiment of the present disclosure provides a transmission system bearing interface modeling method, which includes the steps of: employing an overset grid to compute evolution of multiphase flow within a gear transmission; discretizing a gear body into a plurality of temperature nodes and thermal resistances to establish a thermal network model of a solid domain for temperature field iteration of the gear body; determining a position of any meshing point based on a coordinate system derived from gear dynamics; calculating a heat source for a driving gear and a heat source for a driven gear at each meshing point by combining empirical formulas, CFD data, and heat partition coefficients η; applying the calculated heat sources to the thermal network model of the solid domain for computation; integrating a fluid domain modeling calculation method, a solid-domain thermal network method, and a gear frictional heat calculation method into a unified system; and configuring the unified system with an oil immersion depth, a rotational speed, and a lubricant oil temperature as input parameters, and a churning power loss and a temperature variation of a gear pair as output parameters, thereby achieving rapid comparative analysis between simulation results and experimental data under identical operating conditions.

Embodiment 2: this embodiment provides a transmission system bearing interface modeling system, configured to implement the aforementioned embodiments and preferred implementations. Details already described above are not repeated herein.

This bearing interface modeling system includes a memory storing a computer program and a processor, which, when executing the computer program, implements the steps of the transmission system bearing interface modeling method. For specific examples in this embodiment, reference may be made to the examples described in the aforementioned embodiments and optional implementation modes, which are not repeated herein.

An embodiment of the present disclosure also provides a storage medium, having stored thereon a computer program, which, when executed by the processor, causes the processor to perform the steps according to any of the aforementioned method embodiments.

Alternatively, in this embodiment, the aforementioned storage medium may include, but is not limited to: a universal serial bus (USB) flash drive, a read-only memory (ROM), a random access memory (RAM), a mobile hard disk, a magnetic disk, or an optical disc, as well as any other medium capable of storing a computer program.

An embodiment of the present disclosure also provides an electronic device, including a memory storing a computer program and a processor, which, when executing the computer program, implements the steps of any one of the aforementioned method embodiments.

Alternatively, for specific examples in this embodiment, reference may be made to the examples described in the aforementioned embodiments and optional implementation modes, which are not repeated herein.

The serial numbers of the embodiments in the present application are for descriptive purposes only and do not indicate any preference or superiority among them.

In the aforementioned embodiments of the present application, the description of each embodiment has its own emphasis. For parts not described in detail in a particular embodiment, reference may be made to the relevant description in other embodiments.

With respect to the several embodiments provided in the present application, it is to be understood that the described technical content may also be implemented in other manners.

The foregoing is only the preferred embodiment of the present application. It is to be noted that a person of ordinary skill in the art may make several improvements and embellishments without departing from the principle of the present application, and these improvements and embellishments are regarded as falling within the scope of protection of the present application.

1. A transmission system bearing interface modeling method, comprising the steps of:
establishing a three-dimensional (3D) model of a bearing interface, the bearing interface being a meshing gear pair, and performing grid generation for a fluid domain of the bearing interface within the 3D model;
determining simulation operating conditions, modeling the fluid domain of the bearing interface using a volume of fluid (VOF) model, and capturing phase interfaces in multiphase flow within a gear transmission;
modeling a solid domain of the bearing interface using a thermal network model, and discretizing the solid domain into a plurality of temperature nodes;
calculating frictional heat generation of the gear pair based on gear dynamics to obtain heat sources under meshing conditions, and applying the heat sources to the thermal network model for simulation; and
packaging the modeled bearing interface into an analysis system; and configuring the analysis system with operating condition data of the gear pair as input parameters, and a churning power loss and a temperature variation of the gear pair as output parameters;
wherein
the modeling a solid domain of the bearing interface using a thermal network model, and discretizing the solid domain into a plurality of temperature nodes comprise:
discretizing a driving gear, a driving gear axle, a driven gear, and a driven gear axle into 6, 14, 12, and 13 temperature nodes, respectively;
requiring the following energy equation to be satisfied at each temperature nod TN:
$${\sum }_{j = 1}^{n} {Q}_{ij} + {S}_{i} = {ρ}_{i} {V}_{i} {Cp}_{i} \frac{{dT}_{TN , i}}{dt} ,$$
where Qᵢⱼ is a heat transfer rate between a temperature node TNⱼ and a temperature node TNᵢ; Sᵢ is a heat source added to TNᵢ; ρᵢ, Vᵢ, Cpᵢ, and T_{TN,i} are a density, volume, specific heat capacity, and temperature of TNᵢ, respectively; and n is number of temperature nodes; and
establishing transient iterative energy expressions for each temperature node TN of the gear pair based on the energy equation, as follows:
heat transfer at tooth tip nodes:
$$\frac{2 ( {T}_{a ν e , f l u i d} - {T}_{T N , 1} )}{{R}_{C}} + \frac{{T}_{TN , 2} - {T}_{T N , 1}}{{R}_{d , gear}} + S = {ρ}_{i} {V}_{i} C {p}_{i} \frac{{T}_{TN , 1}^{t + 1} - {T}_{T N , 1}}{Δ t} ,$$
where T_{ave,fluid} is an average fluid temperature; T_{TN,1} is a temperature node at a tooth tip; T_{TN,2} is a temperature node on a gear body close to an outer side thereof and adjacent to the tooth tip; S is a heat source added to temperature node
$${T}_{T N , 1} ; {T}_{TN , 1}^{t + 1}$$
is a temperature of the temperature node at the tooth tip (T_{TN,1}) at time step t+1; Δt is an iteration time step for the solid domain; R_{c} is a convective heat transfer resistance; and R_{d,gear} is a thermal resistance between nodes on the gear body;
heat transfer of gear body nodes along a radial direction:
$$\frac{2 ( {T}_{a ν e , f l u i d} - {T}_{T N , 2} )}{{R}_{C}} + \frac{{T}_{TN , 1} - {T}_{T N , 2}}{{R}_{d , gear}} + \frac{{T}_{TN , 3} - {T}_{T N , 2}}{{R}_{d , gear}} = {ρ}_{i} {V}_{i} C {p}_{i} \frac{{T}_{TN , 2}^{t + 1} - {T}_{T N , 2}}{Δ t} ,$$
where T_{TN,3} is a temperature node adjacent to
$${T}_{T N , 2} ; and {T}_{TN , 2}^{t + 1}$$
is a temperature of the temperature node on the gear body close to the outer side thereof and adjacent to the tooth tip (T_{TN,2}) at time step t+1;
heat transfer between nodes of a gear and a gear axle:
$$\frac{{T}_{T N , m - 1} - {T}_{T N , m}}{{R}_{d , gear}} + \frac{2 ( {T}_{T N , m + 1} - {T}_{T N , m} )}{{R}_{d , axle}} = {ρ}_{i} {V}_{i} C {p}_{i} \frac{{T}_{TN , m}^{t + 1} - {T}_{T N , m}}{Δ t} ,$$
where T_{TN,m-1} is a temperature node in the gear body close to the corresponding axle; T_{TN,m} is a temperature node between the gear body and the axle; T_{TN,m+1} is a temperature node on the axle close to the gear body; R_{d,axle} is a thermal resistance between adjacent nodes on the gear axle; and
$${T}_{TN , m}^{t + 1}$$
is a temperature of the temperature node between the gear body and the axle (T_{TN,m}) at time step t+1;
heat transfer of nodes on the gear axle:
$$\frac{2 ( {T}_{a ν e , f l u i d} - {T}_{T N , m + 1} )}{{R}_{C}} + \frac{{T}_{T N , m} - {T}_{TN , m + 1}}{{R}_{d , axle}} + \frac{{T}_{T N , m + 2} - {T}_{T N , m + 1}}{{R}_{d , a x l e}} = {ρ}_{i} {V}_{i} C {p}_{i} \frac{{T}_{TN , m + 1}^{t + 1} - {T}_{T N , m + 1}}{Δ t} ,$$
where T_{TN,m+2} is a temperature node on the axle adjacent to temperature node
$${T}_{T N , m + 1} ; and {T}_{TN , m + 1}^{t + 1}$$
is a temperature of the temperature node on the axle close to the gear body (T_{TN,m+1}) at time step t+1; and
heat transfer at nodes on a gear axle end face:
$$\frac{2 ( {T}_{a ν e , f l u i d} - {T}_{T N , m + n} )}{{R}_{C}} + \frac{{T}_{T N , m + n - 1} - {T}_{T N , m + n}}{{R}_{d , axle}} = {ρ}_{i} {V}_{i} C {p}_{i} \frac{{T}_{TN , m + n}^{t + 1} - {T}_{T N , m + n}}{Δ t} ,$$
where T_{TN,m+n} is a temperature node of an axle end face; T_{TN,m+n-1} is a temperature node on the axle adjacent to
$${T}_{T N , m + n} ; and {T}_{TN , m + n}^{t + 1}$$
is a temperature of the temperature node at the axle end face (T_{TN,m+n}) at time step t+1; and
according to heat transfer theory, the thermal resistance between nodes on the gear body R_{d,gear}, is given by:
$${R}_{d , gear} = \frac{ln ( {r}_{o u t} / {r}_{i n n e r} )}{2 π λ B} ,$$
where rₒᵤₜ is a radius of an outer TN, which is farther from the axle; rᵢₙₙₑᵣ is a radius of an inner TN, which is closer to the axle; λ is a thermal conductivity; and B is a gear face width;
the thermal resistance between adjacent nodes on the gear axle R_{d,axle} is defined as:
$${R}_{d , a x l e} = \frac{l}{λ A} ,$$
where l is spacing between temperature nodes, and A is a heat transfer area; and
the convective heat transfer resistance R_{c} is as follows:
$${R}_{C} = \frac{{T}_{TN} - {T}_{a ν e , f l u i d}}{Q} ,$$
where T_{TN} represents temperature nodes on the gear and the corresponding axle; and Q represents a convective heat transfer rate at wall surfaces of corresponding regions within the fluid domain.

2. The transmission system bearing interface modeling method according to claim 1, wherein the performing grid generation for a fluid domain of the bearing interface within the 3D model comprises:
dividing the bearing interface into a driving gear region, a driven gear region, and a gear box body region;
assigning the driving gear region and the driven gear region to a foreground grid and the gear box body region to a background grid, with foreground grid elements being hybrid hexahedral grids and background grid elements being structured hexahedral grids;
establishing an overlapping interface for information transfer between the driving gear region and the gear box body region and between the driven gear region and the gear box body region; and
arranging an inflation layer between wall surfaces of the background grid and the foreground grid to ensure a normalized wall distance.

3. The transmission system bearing interface modeling method according to claim 1, wherein the simulation operating conditions comprise an oil immersion depth, a gear rotational speed, and a lubricant oil temperature, and the modeling the fluid domain of the bearing interface using a VOF model comprises:
employing the VOF model to simulate multiphase thermal-flow coupling for heat transfer and fluid flow within the fluid domain of the bearing interface, governed by the following control equations:
a continuity equation:
$$\frac{\partial ρ}{\partial t} + ∇ ( ρ \vec{u} ) = 0 ,$$
where ρ is a fluid density, t is time, and \vec{u} is a fluid velocity vector;
momentum equations:
$$\frac{\partial }{\partial t} ( ρ \vec{u} ) + ∇ ( ρ \vec{u} \vec{u} ) = - ∇ P + ∇ ( μ ( ∇ \vec{u} + ∇ {\vec{u}}^{T} ) ) + ρ \vec{g} + \vec{F} , and$$
$$\vec{F} = σ \frac{{ψ}_{a} {ρ}_{a} {κ}_{a} ∇ {α}_{a} + {ψ}_{l} {ρ}_{l} {κ}_{l} ∇ {α}_{l}}{\frac{1}{2} ( {ρ}_{a} + {ρ}_{l} )} ,$$
where P is pressure, μ is dynamic viscosity, \vec{g} is gravitational acceleration, \vec{F} is surface tension, σ is a surface tension coefficient, Ψₐ is an air volume fraction, βₐ is an air density, κₐ is an air interface curvature, aa is an air volume fraction, Ψₗ is a lubricating oil volume fraction, ρₗ is a lubricating oil density, κₗ is a lubricating oil interface curvature, and αₗ is a lubricating oil volume fraction; and
an energy equation:
$$\frac{\partial }{\partial t} ( ρE ) + ∇ ( \vec{u} ( ρE + P ) ) = ∇ ( {k}_{eff} ∇ T ) + {S}_{E} ,$$
where E is energy, k_{eff} is an effective thermal conductivity, T is temperature, and S_{E} is an energy source term;
applying energy from churning losses to the fluid domain as an energy source term SE, according to the following formula:
$${S}_{E} = \frac{{ψ}_{l} \vert ( {M}_{P} + {M}_{P , axle} ) {n}_{P} - ( {M}_{G} + {M}_{G , axle} ) {n}_{G} \vert}{9550 {V}_{l}} ,$$
where M_{P} and M_{P,axle} represent a churning torque of the driving gear and a churning torque of the driving gear axle; M_{G} and M_{G,axle} represent a churning torque of the driven gear and a churning torque of the driven gear axle, respectively; n_{P} and n_{G} represent a rotational speed of the driving gear and a rotational speed of the driven gear; and Vₗ is a total lubricating oil volume; and
predicting distribution of each phase using the VOF model, and calculating a mixture density p and a mixture viscosity p for each divided grid cell as follows:
$$ρ = {ψ}_{a} {ρ}_{a} + {ψ}_{l} {ρ}_{l} ,$$
$$μ = {ψ}_{a} {μ}_{a} + {ψ}_{l} {μ}_{l} , and$$
$${ψ}_{a} + {ψ}_{l} = 1 ,$$
where μₐ represents air viscosity, and p represents lubricating oil viscosity; and
when Ψₐ=1, it indicates that the grid cell is filled with air; and when Ψₗ=0, it indicates that the grid cell contains no lubricating oil.

4. The transmission system bearing interface modeling method according to claim 1, wherein the calculating frictional heat generation of the gear pair based on gear dynamics to obtain heat sources under meshing conditions, and applying the heat sources to the thermal network model for simulation comprise:
establishing a coordinate system based on gear dynamics and determining each meshing point position during gear pair meshing within the established coordinate system;
calculating a sliding loss and a rolling loss using empirical equations for each meshing point on each line of action;
determining a heat source for the driving gear and a heat source for the driven gear at each meshing point using heat partition coefficients;
calculating an average heat source for each line of action based on the heat source for the driving gear and the heat source for the driven gear at each meshing point;
performing a weighted average based on a length of each line of action to obtain a heat source under a current meshing condition;
averaging the heat sources over all computational cycles in a transmission process to obtain an average heat source for the transmission process; and
applying each calculated heat source data to the thermal network model of the solid domain.

5. The transmission system bearing interface modeling method according to claim 4, wherein the calculating a sliding loss and a rolling loss using empirical equations for each meshing point on each line of action comprises:
calculating a comprehensive curvature radius R_{cc} at a meshing point:
$${R}_{CC} = \frac{{R}_{C , P} {R}_{C , G}}{{R}_{C , P} + {R}_{C , G}} ,$$
where R_{C,P} is a curvature radius of the driving gear at the meshing point, and R_{C,G} is a curvature radius of the driven gear at the meshing point;
determining a sliding velocity as follows:
$${V}_{S , P} = {R}_{C , P} \frac{π {n}_{P}}{30} , and$$
$${V}_{S , G} = {R}_{C , G} \frac{π {n}_{G}}{30} ,$$
where V_{S,P} is a sliding velocity of the driving gear, V_{S,G} is a sliding velocity of the driven gear, n_{P} is a rotational speed of the driving gear, and n_{G} is a rotational speed of the driven gear;
determining a relative sliding velocity V_{RS} and a rolling velocity V_{RR} as follows:
$${V}_{RS} = \vert {V}_{S , P} - {V}_{S , G} \vert , and$$
$${V}_{RR} = \frac{{V}_{S , P} + {V}_{S , G}}{2} ;$$
determining a relative sliding ratio V_{SR} as follows:
$${V}_{SR} = \frac{{V}_{RS}}{{V}_{RR}} ;$$
determining a maximum Hertz contact stress σₘₐₓ as follows:
$${σ}_{max} = \frac{\sqrt{\frac{{F}_{n}}{π {R}_{CC} {L}_{C}} ( \frac{{E}_{P} {E}_{G}}{{E}_{G} ( 1 - {υ}_{P} ) + {E}_{P} ( 1 - {υ}_{G} )} )}}{{10}^{6}} ,$$
where Fn is a normal force, L_{C} is a contact line length at a gear meshing point, E_{P} is an elastic modulus of the driving gear, E_{G} is an elastic modulus of the driven gear, ν_{P} is a Poisson's ratio of driving gear material, and ν_{G} is a Poisson's ratio of a driven gear material;
determining a sliding friction coefficient f as follows:
$$f = {e}^{f ( SR , {σ}_{max} , {μ}^{′} , Ra )} {σ}_{max}^{1.03} {\vert SR \vert}^{1.04} {V}_{RR}^{- 0.1} {μ}^{′0 \text{.72}} {R}_{CC}^{- 0.39} , and$$
$$f ( SR , {σ}_{max} , {μ}^{′} , Ra ) = - 8.92 - 0.35 \vert SR \vert {σ}_{max} {log}_{10} ( {μ}^{′} ) + 2.81 {e}^{- \vert SR \vert {σ}_{max} {log}_{10} ( {μ}^{′} )} + 0.62 {e}^{Ra} ,$$
where μ′ is a dynamic viscosity of the lubricating oil, Ra is surface roughness of the gear, and SR is a sliding ratio;
determining an effective elastic modulus E_{E} as follows:
$${E}_{E} = \frac{2 \times {10}^{6} {E}_{P} {E}_{G}}{{E}_{G} ( 1 - {υ}_{P} ) + {E}_{P} ( 1 - {υ}_{G} )} ;$$
determining a minimum film thickness hₘ as follows:
$${h}_{m} = \frac{3.07 {γ}^{0.57} {{R}_{CC}^{0.4} ( 1 {0}^{- 3} μ {V}_{RR} )}^{0.71}}{{{E}_{E}^{0.03} ( \frac{{F}_{n}}{{L}_{C}} )}^{0.11}} ,$$
where γ is a pressure-viscosity coefficient of the lubricating oil, and μ is a dynamic viscosity of the lubricating oil; and
determining a sliding loss P_{S} and a rolling loss P_{R} as follows:
$${P}_{S} = f {F}_{n} {V}_{S} , and$$
$${P}_{R} = \frac{9 \times 1 {0}^{7} {V}_{RR} {h}_{m} {B}^{′} {ε}_{α}}{cos {β}_{b}} ,$$
where V_{S} is a relative sliding velocity, B′ is an effective gear face width, εₐ is a transverse contact ratio, and β_{b} is a helix angle at base circle.

6. The transmission system bearing interface modeling method according to claim 5, wherein the determining a heat source for the driving gear and a heat source for the driven gear at each meshing point using heat partition coefficients comprises:
calculating a heat partition coefficient for the driving gear and a heat partition coefficient for the driven gear using the following formulas:
$${η}_{P} = \frac{\sqrt{{λ}_{P} {ρ}_{P} {Cp}_{P} {V}_{S , P}}}{\sqrt{{λ}_{P} {ρ}_{P} {Cp}_{P} {V}_{S , P}} + \sqrt{{λ}_{G} {ρ}_{G} {Cp}_{G} {V}_{S , G}}} , and$$
$${η}_{G} = 1 - {η}_{P} ,$$
where η_{P} is a heat partition coefficient of the driving gear, η_{G} is a heat partition coefficient of the driven gear, λ_{P} is a thermal conductivity of the driving gear, ρ_{P} is a density of the driving gear, Cp_{P} is a specific heat capacity of the driving gear, λ_{G} is a thermal conductivity of the driven gear, ρ_{G} is a density of the driven gear, and Cp_{G} is a specific heat capacity of the driven gear; and
calculating a heat source S_{P} generated by heat during driving gear meshing and a heat source S_{G} generated by heat during driven gear meshing based on the heat partition coefficients using the following formulas:
$${S}_{P} = {η}_{P} ( {P}_{S} + {P}_{R} ) , and$$
$${S}_{G} = {η}_{G} ( {P}_{S} + {P}_{R} ) .$$

7. The transmission system bearing interface modeling method according to claim 1, wherein the packaging the modeled bearing interface into an analysis system comprises:
integrating a fluid domain modeling calculation method, a solid-domain thermal network method, and a gear frictional heat calculation method into a unified system; configuring the system with an oil immersion depth, a rotational speed, and a lubricant oil temperature as input parameters, and a churning power loss and a temperature variation of the gear pair as output parameters; and operating the system to acquire operating condition data of the gear pair at the bearing interface, perform simulation calculations on the acquired operating condition data via the integrated computational method, and output heat source calculation results for the bearing interface, achieving a comparative analysis between the simulation results and experimental data.

8. A transmission system bearing interface modeling system, comprising a memory storing a computer program, and a processor, which, when executing the computer program, implements the steps of the transmission system bearing interface modeling method according to claim 1.

9. A transmission system bearing interface modeling system, comprising a memory storing a computer program, and a processor, which, when executing the computer program, implements the steps of the transmission system bearing interface modeling method according to claim 2.

10. A transmission system bearing interface modeling system, comprising a memory storing a computer program, and a processor, which, when executing the computer program, implements the steps of the transmission system bearing interface modeling method according to claim 3.

11. A transmission system bearing interface modeling system, comprising a memory storing a computer program, and a processor, which, when executing the computer program, implements the steps of the transmission system bearing interface modeling method according to claim 4.

12. A transmission system bearing interface modeling system, comprising a memory storing a computer program, and a processor, which, when executing the computer program, implements the steps of the transmission system bearing interface modeling method according to claim 5.

13. A transmission system bearing interface modeling system, comprising a memory storing a computer program, and a processor, which, when executing the computer program, implements the steps of the transmission system bearing interface modeling method according to claim 6.

14. A transmission system bearing interface modeling system, comprising a memory storing a computer program, and a processor, which, when executing the computer program, implements the steps of the transmission system bearing interface modeling method according to claim 7.

15. A storage medium, having stored thereon a computer program, which, when executed by a processor, causes the processor to perform the steps of the transmission system bearing interface modeling method according to claim 1.

16. A storage medium, having stored thereon a computer program, which, when executed by a processor, causes the processor to perform the steps of the transmission system bearing interface modeling method according to claim 2.

17. A storage medium, having stored thereon a computer program, which, when executed by a processor, causes the processor to perform the steps of the transmission system bearing interface modeling method according to claim 3.

18. A storage medium, having stored thereon a computer program, which, when executed by a processor, causes the processor to perform the steps of the transmission system bearing interface modeling method according to claim 4.

19. A storage medium, having stored thereon a computer program, which, when executed by a processor, causes the processor to perform the steps of the transmission system bearing interface modeling method according to claim 5.

20. A storage medium, having stored thereon a computer program, which, when executed by a processor, causes the processor to perform the steps of the transmission system bearing interface modeling method according to claim 6.
